(19) United States
(12) Patent Application Publication
(10) Pub. No.: US 2024/0047599 A1
(43) Pub. Date: Feb. 8, 2024

(54) SEMICONDUCTOR DEVICE AND PHOTOSENSITIVE DEVICE

(71) Applicant: TCL CHINA STAR OPTOELECTRONICS TECHNOLOGY CO., LTD., Shenzhen, Guangdong (CN)

(72) Inventor: Zhiwei TAN, Shenzhen, Guangdong (CN)

(21) Appl. No.: 17/594,046

(22) PCT Filed: Jun. 15, 2021
(86) PCT No.: PCT/CN2021/100145

§ 371 Date: Sep. 30, 2021

(30) Foreign Application Priority Data
May 31, 2021 (CN) 202110604648.X

(51) Int. Cl. H01L 31/113; H01L 31/0392; H01L 31/0224

(52) U.S. Cl. CPC H01L 31/1136; H01L 31/03921; H01L 31/022408; H01L 31/022475; H01L 31/202

(57) ABSTRACT

A semiconductor device and a photosensitive device are provided. The semiconductor device includes a substrate and a photosensitive thin film transistor. The photosensitive thin film transistor includes a first metal layer, an insulating layer, a photosensitive semiconductor layer, a photosensitive ohmic contact layer, and a second metal layer. At least one side of the photosensitive ohmic contact layer protrudes from the second metal layer arranged on it, which increases an irradiated area of the photosensitive ohmic contact layer, thereby improving a photo-responsiveness of the photosensitive thin film transistor.

### FIELD OF DISCLOSURE

The present disclosure relates to the field of optical sensing technologies, in particular to a semiconductor device and a photosensitive device.

### BACKGROUND

Photosensitive sensors are important elements of Internet of Things. Especially, in a case of low light, the photosensitive sensor is suitable for many application scenarios. As a production process of thin film transistors (TFTs) has a huge industrial foundation and mature manufacturing process, forming the photosensitive devices by using the TFT has many industrial advantages. The TFT includes a photosensitive semiconductor layer for photosensitive. The photosensitive semiconductor layer is sensitive to light. In a case of strong light, the photosensitive semiconductor layer is irradiated with high light intensity, and a current becomes larger, which can obtain higher photocurrent responsivity and high induction sensitivity. In the case of low light, the photosensitive semiconductor layer is irradiated with weak light intensity, the current becomes small, and the obtained photocurrent responsiveness is small, resulting in low sensitivity. Therefore, a current key issue that needs to be broken through is how to improve the photocurrent responsiveness of the TFTs under low light conditions.

Accordingly, it is necessary to provide a semiconductor device and a photosensitive device to solve the above technical problems.

### SUMMARY OF DISCLOSURE

The present disclosure provides a semiconductor device and a photosensitive device, which solves the technical problem of low photocurrent responsiveness of sensing thin film transistors of existing semiconductor devices under low light conditions.

The present disclosure provides a semiconductor device, including a substrate and a photosensitive thin film transistor disposed on the substrate. The photosensitive thin film transistor is a bottom gate structure, and the photosensitive thin film transistor includes:
a first metal layer disposed on the substrate;
an insulating layer covering the substrate and the first metal layer;
a photosensitive semiconductor layer disposed on the insulating layer and aligned with the first metal layer;
a photosensitive ohmic contact layer disposed on the photosensitive semiconductor layer and including a first photosensitive ohmic contact portion and a second photosensitive ohmic contact portion that are arranged at intervals; and
a second metal layer disposed on the first photosensitive ohmic contact portion and the second photosensitive ohmic contact portion.

An orthographic projection of the second metal layer on the substrate is a first orthographic projection, an orthographic projection of the photosensitive ohmic contact layer on the substrate is a second orthographic projection, at least one portion of the first orthographic projection is in the second orthographic projection, a distance between at least one edge of the first orthographic projection and an edge of the second orthographic projection is greater than 0, and the distance is within a preset range.

According to the semiconductor device of the present disclosure, the preset range is greater than or equal to 0.4 micrometers.

According to the semiconductor device of the present disclosure, the preset range is greater than 0 micrometers and less than or equal to 0.8 micrometers.

According to the semiconductor device of the present disclosure, the second metal layer includes a first electrode disposed on the first photosensitive ohmic contact portion and a second electrode disposed on the second photosensitive ohmic contact portion.

An orthographic projection of the first electrode on the substrate is in an orthographic projection of the first photosensitive ohmic contact portion on the substrate, and/or an orthographic projection of the second electrode on the substrate is in an orthographic projection of the second photosensitive ohmic contact portion on the substrate.

According to the semiconductor device of the present disclosure, distances of any two points of an edge of the orthographic projection of the first electrode on the substrate to an edge of the orthographic projection of the first photosensitive ohmic contact portion on the substrate are equal.

According to the semiconductor device of the present disclosure, distances of any two points of an edge of the orthographic projection of the second electrode on the substrate to an edge of the orthographic projection of the second photosensitive ohmic contact portion on the substrate are equal.

According to the semiconductor device of the present disclosure, the photosensitive semiconductor layer and the photosensitive ohmic contact layer are formed through a same mask process.

According to the semiconductor device of the present disclosure, material of the photosensitive semiconductor layer includes an amorphous silicon, and material of the photosensitive ohmic contact layer includes a doped amorphous silicon.

According to the semiconductor device of the present disclosure, the photosensitive semiconductor layer includes a first side surface and a second side surface that are opposite to each other.

A side of the first photosensitive ohmic contact portion away from the second photosensitive ohmic contact portion is on a same plane as the first side surface of the photosensitive semiconductor layer, and a side of the second photosensitive ohmic contact portion away from the first photosensitive ohmic contact portion is on a same plane as the second side surface of the photosensitive semiconductor layer.

According to the semiconductor device of the present disclosure, the semiconductor device further includes: a passivation layer, a via hole, and a transparent conductive layer. The passivation layer covers the insulating layer, the photosensitive semiconductor layer, the photosensitive ohmic contact layer, and the second metal layer. The via hole extends through the passivation layer and is connected to the second metal layer. The transparent conductive layer is disposed in the via hole and extends to the passivation layer. The transparent conductive layer is electrically connected to the second metal layer through the via hole.

The present disclosure provides a semiconductor device, including a substrate and a photosensitive thin film transistor disposed on the substrate, and the photosensitive thin film transistor includes:
a first metal layer disposed on the substrate;
an insulating layer covering the substrate and the first metal layer;
a photosensitive semiconductor layer disposed on the insulating layer and aligned with the first metal layer;
a photosensitive ohmic contact layer disposed on the photosensitive semiconductor layer and including a first photosensitive ohmic contact portion and a second photosensitive ohmic contact portion that are arranged at intervals; and
a second metal layer disposed on the first photosensitive ohmic contact portion and the second photosensitive ohmic contact portion.

An orthographic projection of the second metal layer on the substrate is a first orthographic projection, an orthographic projection of the photosensitive ohmic contact layer on the substrate is a second orthographic projection, at least one portion of the first orthographic projection is in the second orthographic projection, a distance between at least one edge of the first orthographic projection and an edge of the second orthographic projection is greater than 0, and the distance is within a preset range.

According to the semiconductor device of the present disclosure, the preset range is greater than or equal to 0.4 micrometers.

According to the semiconductor device of the present disclosure, the preset range is greater than 0 micrometers and less than or equal to 0.8 micrometers.

According to the semiconductor device of the present disclosure, the second metal layer includes a first electrode disposed on the first photosensitive ohmic contact portion and a second electrode disposed on the second photosensitive ohmic contact portion.

An orthographic projection of the first electrode on the substrate is in an orthographic projection of the first photosensitive ohmic contact portion on the substrate, and/or an orthographic projection of the second electrode on the substrate is in an orthographic projection of the second photosensitive ohmic contact portion on the substrate.

According to the semiconductor device of the present disclosure, distances of any two points of an edge of the orthographic projection of the first electrode on the substrate to an edge of the orthographic projection of the first photosensitive ohmic contact portion on the substrate are equal.

According to the semiconductor device of the present disclosure, distances of any two points of an edge of the orthographic projection of the second electrode on the substrate to an edge of the orthographic projection of the second photosensitive ohmic contact portion on the substrate are equal.

According to the semiconductor device of the present disclosure, material of the photosensitive semiconductor layer includes an amorphous silicon, and material of the photosensitive ohmic contact layer includes a doped amorphous silicon.

According to the semiconductor device of the present disclosure, the photosensitive semiconductor layer includes a first side surface and a second side surface that are opposite to each other.

A side of the first photosensitive ohmic contact portion away from the second photosensitive ohmic contact portion is on a same plane as the first side surface of the photosensitive semiconductor layer, and a side of the second photosensitive ohmic contact portion away from the first photosensitive ohmic contact portion is on a same plane as the second side surface of the photosensitive semiconductor layer.

According to the semiconductor device of the present disclosure, the semiconductor device further includes: a passivation layer, a via hole, and a transparent conductive layer. The passivation layer covers the insulating layer, the photosensitive semiconductor layer, the photosensitive ohmic contact layer, and the second metal layer. The via hole extends through the passivation layer and is connected to the second metal layer. The transparent conductive layer is disposed in the via hole and extends to the passivation layer. The transparent conductive layer is electrically connected to the second metal layer through the via hole.

The present disclosure provides a photosensitive device, including: a semiconductor device. The semiconductor device includes a substrate and a photosensitive thin film transistor disposed on the substrate, and the photosensitive thin film transistor includes:
a first metal layer disposed on the substrate;
an insulating layer covering the substrate and the first metal layer;
a photosensitive semiconductor layer disposed on the insulating layer and aligned with the first metal layer;
a photosensitive ohmic contact layer disposed on the photosensitive semiconductor layer and including a first photosensitive ohmic contact portion and a second photosensitive ohmic contact portion that are arranged at intervals; and
a second metal layer disposed on the first photosensitive ohmic contact portion and the second photosensitive ohmic contact portion.

An orthographic projection of the second metal layer on the substrate is a first orthographic projection, an orthographic projection of the photosensitive ohmic contact layer on the substrate is a second orthographic projection, at least one portion of the first orthographic projection is in the second orthographic projection, a distance between at least one edge of the first orthographic projection and an edge of the second orthographic projection is greater than 0, and the distance is within a preset range.

In the semiconductor device and the photosensitive device of the present disclosure, at least one portion of the first orthographic projection of the second metal layer on the substrate is in the second orthographic projection of the photosensitive ohmic contact layer on the substrate. Also, a distance between at least one edge of the first orthographic projection and an edge of the second orthographic projection is greater than 0, and the distance is within a preset range. Thus, at least one side of the photosensitive ohmic contact layer protrudes from the second metal layer arranged on it, which reduces an area covered by the second metal layer of the photosensitive ohmic contact layer, thereby increasing an irradiated area of the photosensitive ohmic contact layer, which is conducive to improving the photocurrent responsiveness of the photosensitive thin film transistor.

### BRIEF DESCRIPTION OF DRAWINGS

In order to explain technical solutions of embodiments or in the prior art more clearly, the following will briefly introduce drawings that need to be used in a description of the embodiments or the prior art. Apparently, the drawings in the following description are only some embodiments of the application. For those of ordinary skill in the art, other drawings can be obtained based on these drawings without creative efforts.

FIG. 1 is a schematic diagram of a semiconductor device of an embodiment of the present disclosure.

FIG. 2 is a graph showing variation curves of photo-generated currents measured under different light intensities of a semiconductor device of an embodiment of the present disclosure.

FIG. 3 is a flowchart of a manufacturing method of a semiconductor device of an embodiment of the present disclosure.

FIG. 4 is a schematic diagram of a formation of a first metal layer in the manufacturing method of the semiconductor device of the embodiment of the present disclosure.

FIG. 5 is a schematic diagram of a formation of an insulating layer in the manufacturing method of the semiconductor device of the embodiment of the present disclosure.

FIG. 6a is a schematic diagram of a formation of a first island-shaped pattern in the manufacturing method of the semiconductor device of the embodiment of the present disclosure.

FIG. 6b is a schematic diagram of a formation of a second island-shaped pattern in the manufacturing method of the semiconductor device of the embodiment of the present disclosure.

FIG. 6c is a schematic diagram of a formation of a third island-shaped pattern in the manufacturing method of the semiconductor device of the embodiment of the present disclosure.

FIG. 7 is a schematic diagram of a formation of a passivation layer in the manufacturing method of the semiconductor device of the embodiment of the present disclosure.

FIG. 8 is a schematic diagram of a formation of a via hole in the manufacturing method of the semiconductor device of the embodiment of the present disclosure.

FIG. 9 is a schematic diagram of a formation of a transparent conductive layer in the manufacturing method of the semiconductor device of the embodiment of the present disclosure.

### DETAILED DESCRIPTION

The technical solutions in the embodiments of the present disclosure will be clearly and completely described below in conjunction with the drawings in the embodiments of the present disclosure. Apparently, the described embodiments are only a part of the embodiments of the present disclosure, rather than all of the embodiments. Based on the embodiments in the present disclosure, all other embodiments obtained by those skilled in the art without creative efforts shall fall within the protection scope of the present disclosure. In addition, it should be understood that the specific embodiments described herein are only used to illustrate and explain the present disclosure, and are not used to limit the present disclosure. In the present disclosure, if no explanation is made to the contrary, orientation terms, such as “upper” and “lower”, usually refer to upper and lower sides of a device in actual use or working state, and specifically refer to directions in the drawings. Also, “inner” and “outer” refer to an outline of the device.

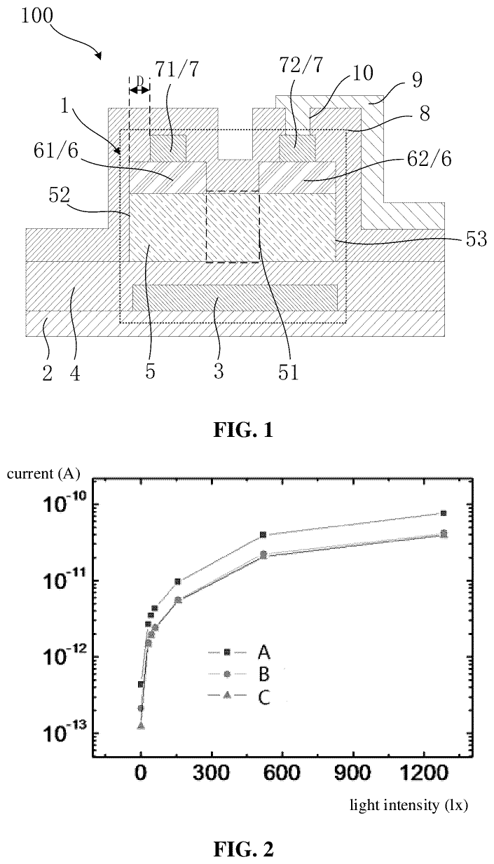

As shown in FIG. 1, an embodiment of the present disclosure provides a semiconductor device 100. The semiconductor device includes a photosensitive thin film transistor 1 and a substrate 2. The photosensitive thin film transistor 1 is disposed on the substrate 2. The photosensitive thin film transistor 1 includes a first metal layer 3, an insulating layer 4 (i.e., a gate insulating layer), a photosensitive semiconductor layer 5, a photosensitive ohmic contact layer 6 (e.g., an N+ semiconductor layer), a second metal layer 7, a passivation layer 8, and a transparent conductive layer 9 which are sequentially disposed on the substrate 2 in a direction perpendicular to the substrate 2 (e.g., a longitudinal direction).

The first metal layer 3 is disposed on the substrate 2. The insulating layer 4 covers the substrate 2 and the first metal layer 3. The photosensitive semiconductor layer 5 is disposed on the insulating layer 4 and aligned with the first metal layer 3. The photosensitive ohmic contact layer 6 is disposed on the photosensitive semiconductor layer 5 and includes a first photosensitive ohmic contact portion 61 and a second photosensitive ohmic contact portion 62 which are arranged at intervals. The second metal layer 7 is disposed on the first photosensitive ohmic contact portion 61 and the second photosensitive ohmic contact portion 62. The passivation layer 8 covers the insulating layer 4, the photosensitive semiconductor layer 5, the photosensitive ohmic contact layer 6, and the second metal layer 7. The transparent conductive layer 9 is disposed on the passivation layer 8, and is electrically connected to the second metal layer 7 through a via hole 10 extending through the passivation layer 8.

Specifically, in the embodiment of the present disclosure, the photosensitive thin film transistor 1 is a bottom gate structure, and the first metal layer 3 is a gate of the photosensitive thin film transistor 1.

Specifically, material of the photosensitive semiconductor layer 5 includes amorphous silicon (a-Si), which is not limited thereto. Material of the photosensitive ohmic contact layer 6 includes doped amorphous silicon, such as N+ amorphous silicon, and specifically may be phosphorus-doped amorphous silicon, and the specific ion to be doped is not limited to this. Both the photosensitive semiconductor layer 5 and the photosensitive ohmic contact layer 6 can generate photo-generated carriers when irradiated with external light. Specifically, a conductivity of the N+ amorphous silicon is greater than that of the amorphous silicon, and the amount of photo-generated carriers generated when the N+ amorphous silicon is irradiated is greater than the amount of photo-generated carriers generated when the amorphous silicon is irradiated. It is understandable that a photosensitivity of the photosensitive ohmic contact layer 6 is greater than that of the photosensitive semiconductor layer 5.

Specifically, the first photosensitive ohmic contact portion 61 and the second photosensitive ohmic contact portion 62 of the photosensitive ohmic contact layer 6 are arranged at intervals. It can be understood that a gap is formed between the first photosensitive ohmic contact portion 61 and the second photosensitive ohmic contact portion 62. A portion of the photosensitive semiconductor layer 5 corresponding to the gap is a channel region 51.

Specifically, the photosensitive semiconductor layer 5 includes a first side surface 52 and a second side surface 53 arranged oppositely. A side of the first photosensitive ohmic contact portion 61 away from the second photosensitive ohmic contact portion 62 is on a same plane as the first side surface 52 of the photosensitive semiconductor layer 5. Also, a side of the second photosensitive ohmic contact portion 62 away from the first photosensitive ohmic contact portion 61 is on a same plane as the second side surface 53 of the photosensitive semiconductor layer 5.

It should be noted that the “same plane” in the embodiment of the present disclosure includes: absolute coplanar or approximately coplanar. The approximately coplanar means that an angle between two planes is less than 5 degrees. In addition, for the convenience of description, the first side surface and the second side surface in the embodiment of the present disclosure are approximately flat surfaces, but they are uneven surfaces in actual.

In a specific embodiment, a portion of the photosensitive semiconductor layer 5 except for the channel region 51 (exposed portion) has substantially a same plane pattern as the photosensitive ohmic contact layer 6. It is understandable that the photosensitive semiconductor layer 5 and the photosensitive ohmic contact layer 6 can be fabricated through a same mask process, for example, a half-tone mask (HTM) or a gray-tone mask (GTM).

Specifically, the second metal layer 7 is a source/drain electrode layer of the photosensitive thin film transistor 1. As shown in FIG. 1, the second metal layer 7 includes a first electrode 71 on the first photosensitive ohmic contact portion 61 and a second electrode 72 on the second photosensitive ohmic contact portion 62. In a specific embodiment, the first electrode 71 is a source, and the second electrode 72 is a drain.

Specifically, an orthographic projection of the second metal layer 7 on the substrate 2 is a first orthographic projection. An orthographic projection of the photosensitive ohmic contact layer 6 on the substrate 2 is a second orthographic projection. At least one portion of the first orthographic projection is in the second orthographic projection. A distance between at least one edge of the first orthographic projection and an edge of the second orthographic projection is greater than 0, and the distance D is within a preset range

It can be understood that at least one side of the photosensitive ohmic contact layer 6 protrudes laterally from the corresponding second metal layer 7. That is, at least one portion of the photosensitive ohmic contact layer 6 is not covered by the second metal layer 7 arranged on it. Moreover, a width of the portion of the photosensitive ohmic contact layer 6 not covered by the second metal layer 7 (i.e., the D shown in FIG. 1) is within the preset range. The portion of the photosensitive ohmic contact layer 6 that is not covered by the second metal layer 7 can be irradiated by external light to generate photo-generated carriers. Therefore, controlling values of the preset range can effectively control an irradiated area of the photosensitive ohmic contact layer 6. Thus, the amount of photo-generated carriers generated by the photosensitive ohmic contact layer 6 can be effectively controlled, and a photo-responsiveness of the photosensitive ohmic contact layer 6 can be improved.

It should be noted that the width of the portion of the photosensitive ohmic contact layer 6 not covered by the second metal layer 7 (the portion of the photosensitive ohmic contact layer 6 protruding from the second metal layer 7) is the distance between the first orthographic projection and the second orthographic projection in the second orthographic projection.

Specifically, the first orthographic projection includes an orthographic projection of the first electrode 71 on the substrate 2 and an orthographic projection of the second electrode 72 on the substrate 2. The second orthographic projection includes an orthographic projection of the first photosensitive ohmic contact portion 61 on the substrate 2 and an orthographic projection of the second photosensitive ohmic contact portion 62 on the substrate 2.

Specifically, the orthographic projection of the first electrode 71 on the substrate 2 is in the orthographic projection of the first photosensitive ohmic contact portion 61 on the substrate 2, and/or the orthographic projection of the second electrode 72 on the substrate 2 is in the orthographic projection of the second photosensitive ohmic contact portion 62 on the substrate 2. It should be noted that the orthographic projection of the first electrode 71 on the substrate 2 is in the orthographic projection of the first photosensitive ohmic contact portion 61 on the substrate 2 means that the orthographic projection of the first electrode 71 on the substrate 2 is covered by the orthographic projection of the first photosensitive ohmic contact portion 61 on the substrate 2. Moreover, the distance between the edge of either side of the orthographic projection of the first electrode 71 on the substrate 2 and the edge of the orthographic projection of the first photosensitive ohmic contact portion 61 on the substrate 2 is greater than zero. Similarly, the orthographic projection of the second electrode 72 on the substrate 2 is in the orthographic projection of the second photosensitive ohmic contact portion 62 on the substrate 2 means that the orthographic projection of the second electrode 72 on the substrate 2 is covered by the orthographic projection of the second photosensitive ohmic contact portion 62 on the substrate 2. Moreover, the distance between the edge of either side of the orthographic projection of the second electrode 72 on the substrate 2 and the edge of the orthographic projection of the second photosensitive ohmic contact portion 62 on the substrate 2 is greater than zero.

The orthographic projection of the first electrode 71 on the substrate 2 is in the orthographic projection of the first photosensitive ohmic contact portion 61 on the substrate 2. The orthographic projection of the second electrode 72 on the substrate 2 is in the orthographic projection of the second photosensitive ohmic contact portion 62 on the substrate 2. Moreover, distances of any two points of the edge of the orthographic projection of the first electrode 71 on the substrate 2 to the edge of the orthographic projection of the first photosensitive ohmic contact portion 61 on the substrate 2 are equal. Distances of any two points of the edge of the orthographic projection of the second electrode 72 on the substrate 2 to the edge of the orthographic projection of the second photosensitive ohmic contact portion 62 on the substrate 2 are equal. At this time, the first electrode 71 and the second electrode 72 may be electrically connected to other conductive layers through via holes.

It can be understood that, in the foregoing embodiment, any one side of the first photosensitive ohmic contact portion 61 protrudes laterally from the first electrode 71. Any one side of the second photosensitive ohmic contact portion 62 protrudes laterally from the second electrode 72. Moreover, a width of a portion of the first photosensitive ohmic contact portion 61 protruding from the first electrode 71 (i.e., the D shown in FIG. 1) is within the preset range. A width of a portion of the second photosensitive ohmic contact portion 62 protruding from the second electrode 72 is within the preset range.

The orthographic projection of the first electrode 71 on the substrate 2 is in the orthographic projection of the first photosensitive ohmic contact portion 61 on the substrate 2, and the orthographic projection of the second electrode 72 on the substrate 2 is in the orthographic projection of the second photosensitive ohmic contact portion 62 on the substrate 2. For example, two opposite sides of the first photosensitive ohmic contact portion 61 protrude laterally from the first electrode 71. Moreover, any one side of the second photosensitive ohmic contact portion 62 protrudes laterally from the second electrode 72. The distances of any two points of the edge of the orthographic projection of the second electrode 72 on the substrate 2 to the edge of the orthographic projection of the second photosensitive ohmic contact portion 62 on the substrate 2 are equal.

It should be noted that “equal” in the embodiments of the present disclosure includes absolute equal or approximately equal. The approximately equal means that a ratio between a maximum value and a minimum value of the distance ranges from 0.95 to 1.05.

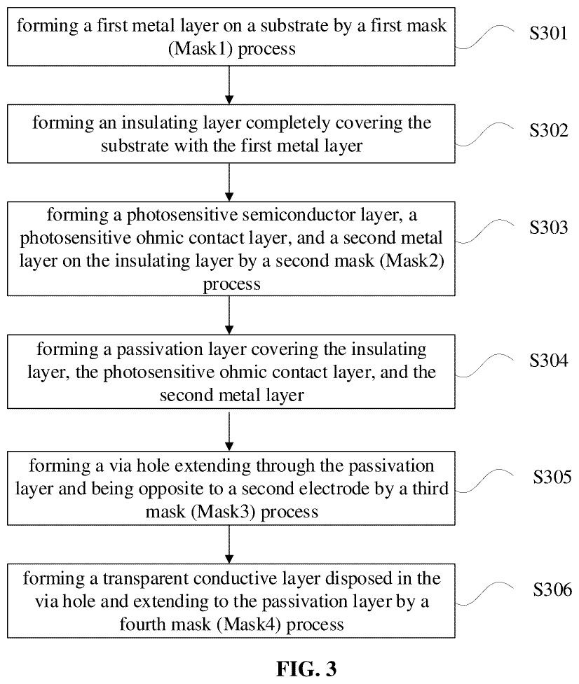

Specifically, as shown in FIG. 1 and FIG. 2, when a thickness of the channel region 51 of the photosensitive semiconductor layer 5 is 150 nanometers, and the photosensitive ohmic contact layer 6 protrudes laterally from the corresponding second metal layer 7 with widths of 0 μm, 0.4 μm, and 0.8 μm, variation curves of photo-generated current measured by the photosensitive thin film transistor 1 under different light intensities are represented by a curve A, a curve B, and a curve C, respectively. It can be seen from FIG. 2 that the widths of the photosensitive ohmic contact layer 6 protruding from the corresponding second metal layer 7 are 0 μm, 0.4 μm, and 0.8 μm, respectively. The intensity of the photo-generated current of the photosensitive thin film transistor 1 increases with the increase of the light intensity. Moreover, in a range of light intensity from 0 to 50 lux (lx) (under low light conditions), the photo-responsivities of the photosensitive thin film transistor 1 when the widths of the photosensitive ohmic contact layer 6 protruding from the corresponding second metal layer 7 are 0.4 μm and 0.8 μm are greater than the photo-responsivity of the photosensitive thin film transistor 1 when the width of the photosensitive ohmic contact layer 6 protruding from the corresponding second metal layer 7 is 0 μm. Also, the photo-responsivity of the photosensitive thin film transistor 1 when the width of the photosensitive ohmic contact layer 6 protruding from the corresponding second metal layer 7 is 0.8 μm is greater than the photo-responsivity of the photosensitive thin film transistor 1 when the width of the photosensitive ohmic contact layer 6 protruding from the corresponding second metal layer 7 is 0.4 μm. Specifically, when the width of the photosensitive ohmic contact layer 6 protruding from the corresponding second metal layer 7 is increased from 0 to 0.4 μm, the photo-responsivity can be increased by 50%. When the width of the photosensitive ohmic contact layer 6 protruding from the corresponding second metal layer 7 is increased from 0.4 μm to 0.8 μm, the photo-responsivity can be further improved, but the improvement is small.

It should be noted that a photo-generated current ratio of the photosensitive thin film transistor 1 under bright and dark illumination is more critical in actual application scenarios. In the embodiments of the present disclosure, the photo-responsivity under low light conditions is defined as a ratio of the photo-generated current of the photosensitive thin film transistor 1 when the light intensity is 50 lx to the photo-generated current of the photosensitive thin film transistor 1 when the light intensity is 0.

The preset range can be set to be greater than or equal to 0.4 μm, it ensures that the width of the photosensitive ohmic contact layer 6 protruding from the corresponding second metal layer 7 is greater than 0.4 μm. Thus, the photo-responsivity of the photosensitive ohmic contact layer 6 under low light conditions is effectively improved, and the photo-responsivity of the photosensitive thin film transistor 1 under low light conditions is improved. The preset range can be set to be greater than 0 and less than or equal to 0.8 μm. At this time, the photo-responsivity of the photosensitive ohmic contact layer 6 under low light conditions can also be effectively improved, thereby improving the photo-responsivity of the photosensitive thin film transistor 1 under low light conditions.

As the width of the photosensitive ohmic contact layer 6 protruding from the corresponding second metal layer 7 is increased from 0.4 μm to 0.8 μm, the photo-responsivity can be further improved, but the improvement is small. In the embodiments of the present disclosure, the preset range can also be set to be greater than or equal to 0.4 μm and less than or equal to 0.8 μm. In this way, the photo-responsivity of the photosensitive thin film transistor 1 under low light conditions can be greatly improved, and it can prevent excessively increasing the width of the photosensitive ohmic contact layer 6 protruding from the corresponding second metal layer 7. Thus, it prevents an increase in a volume of a device structure caused by excessively increasing the width of the photosensitive ohmic contact layer 6, or prevents that the width of the second metal layer 7 is too small caused by excessively reducing the width of the second metal layer 7, thereby affecting the stability of the device.

Specifically, as shown in FIG. 1, the passivation layer 8 is provided with a via hole 10 that extends through the passivation layer 8. The via hole 10 is connected to the second electrode 72. The transparent conductive layer 9 is also disposed in the via hole 10 and extends to the passivation layer 8. The transparent conductive layer 9 is electrically connected to the second metal layer 7 through the via hole 10, and specifically to the second electrode 72. Material of the transparent conductive layer 9 includes indium tin oxide (ITO), which is used to derive the photo-generated carriers generated by the photosensitive semiconductor layer 5 and the photosensitive ohmic contact layer 6.

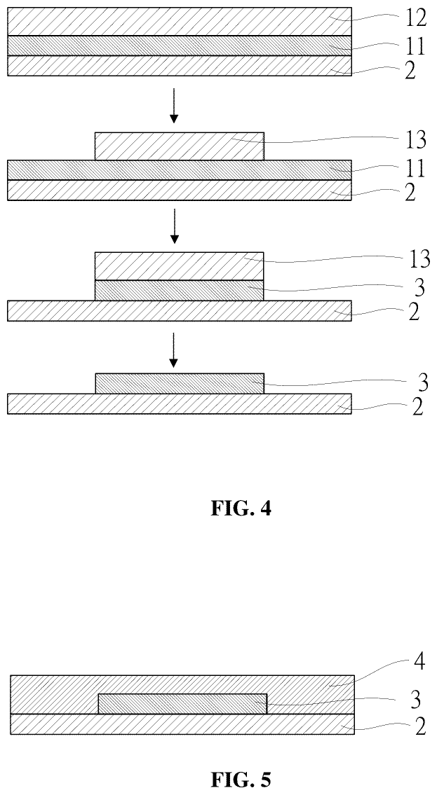

The photosensitive thin film transistor 1 can be formed by a four mask (4Mask) process. As shown in FIG. 3, a manufacturing method of the photosensitive thin film transistor with the four mask process includes steps S301 to S306.

In a step S301, a first metal layer is formed on a substrate by a first mask (Mask1) process.

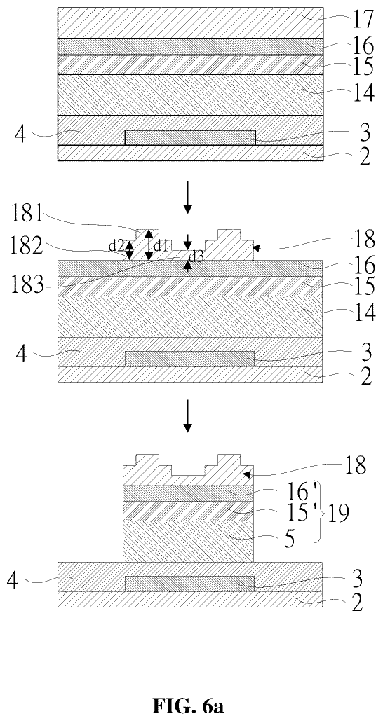

As shown in FIG. 4, a first metal film 11 and a first photoresist film 12 are sequentially covered on a substrate 2, and then the first photoresist film 12 is patterned through the first mask (Mask1) to form a first photoresist pattern 13. Sequentially, the first metal film 11 is etched using the first photoresist pattern 13 as a mask to form a first metal layer 3. Finally, the first photoresist pattern 13 is removed. Specifically, the first photoresist film 12 is patterned using exposure and development technology. For the first metal film 11, either dry-etching or wet-etching may be used.

In a step S302, an insulating layer completely covering the substrate with the first metal layer is formed.

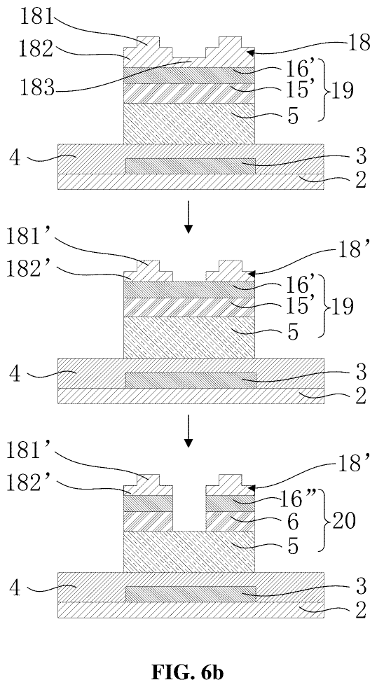

As shown in FIG. 5, the insulating layer 4 covers the substrate 2 with the first metal layer 3. Specifically, material of the insulating layer 4 may be silicon nitride (SiNx), silicon oxide (SiOx), silicon oxynitride (SiON), etc. or a combination thereof.

In a step S303, a photosensitive semiconductor layer, a photosensitive ohmic contact layer, and a second metal layer are formed on the insulating layer by a second mask (Mask2) process.

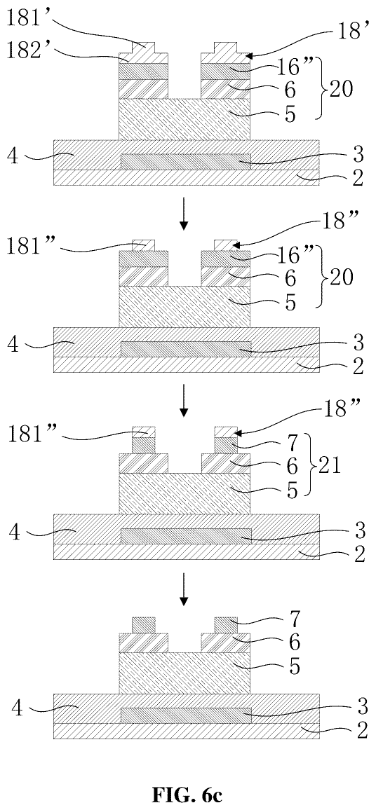

Specifically, the second mask (Mask2) is a half-tone mask HTM or a gray-tone mask GTM. As shown in FIG. 6a to FIG. 6c, a photosensitive semiconductor film 14, a photosensitive ohmic contact film 15, a second metal film 16, and a second photoresist film 17 are sequentially covered on a surface of the insulating layer 4 away from the substrate 2. Sequentially, the second photoresist film 17 is patterned through the second mask to form a second photoresist pattern 18 with different thicknesses. Finally, the photosensitive semiconductor film 14, the photosensitive ohmic contact film 15, and the second metal film 16 are dry-etched using the second photoresist pattern 18 as a mask to form a photosensitive semiconductor layer 5, a photosensitive ohmic contact layer 6, and a second metal layer 7. Specifically, as shown in FIG. 6a, the second photoresist pattern 18 includes a first photoresist portion 181 having a first thickness d1, a second photoresist portion 182 having a second thickness d2, and a third photoresist portion 183 having a third thickness d3. The first thickness d1 is greater than the second thickness d2, and the second thickness d2 is greater than the third thickness d3.

The step of dry-etching the photosensitive semiconductor film 14, the photosensitive ohmic contact film 15, and the second metal film 16 using the second photosensitive pattern 18 as the mask includes the following steps:

As shown in FIG. 6a, the photosensitive semiconductor film 14, the photosensitive ohmic contact film 15, and the second metal film 16 are subjected to a first dry-etching process using the second photoresist pattern 18 as the mask to form a first island-shaped pattern 19 which exposes a portion of the insulating layer 4. The first island-shaped pattern 19 includes the photosensitive semiconductor layer 5, a photosensitive ohmic contact film 15′, and a second metal film 16′.

As shown in FIG. 6b, the second photoresist pattern 18 is subjected to a first ashing process to remove the third photoresist portion 183 and reduce thicknesses of the first photoresist portion 181 and the second photoresist portion 182, thereby forming a second photoresist pattern 18′ including a first photoresist portion 181′ and a second photoresist portion 182′. Sequentially, the second photoresist pattern 18′ being subjected to the first ashing process serves as a mask, and the photosensitive ohmic contact film 15′ and the second metal film 16′ are subjected to a second dry-etching process to form a second island-shaped pattern 20 which exposes a channel region of the photosensitive semiconductor layer 5. The second island-shaped pattern 20 includes the photosensitive semiconductor layer 5, the photosensitive ohmic contact layer 6, and a second metal film 16″.

As shown in FIG. 6c, the second photoresist pattern 18′ is subjected to a second ashing process to remove the second photoresist portion 182′ and reduce a thickness of the first photoresist portion 181′, thereby forming a second photoresist pattern 18″ including a first photoresist portion 181″. Sequentially, the second photoresist pattern 18″ being subjected to the second ashing process serves as a mask, and the second metal film 16″ are subjected to a third dry-etching process to form a third island-shaped pattern 21 which exposes a portion of the photosensitive semiconductor layer 5. The third island-shaped pattern 21 includes the photosensitive semiconductor layer 5, the photosensitive ohmic contact layer 6, and the second metal layer 7. Finally, the second photoresist pattern 18″ is removed after the second ashing process.

In a step S304, a passivation layer covering the insulating layer, the photosensitive ohmic contact layer, and the second metal layer is formed.

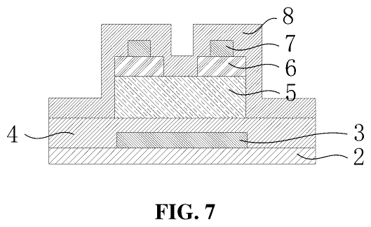

Specifically, as shown in FIG. 7, the passivation layer 8 is covered on the insulating layer 4, the photosensitive ohmic contact layer 6, and the second metal layer 7. Material of the passivation layer 8 may be silicon nitride (SiNx), silicon oxide (SiOx), silicon oxynitride (SiON), etc. or a combination thereof.

In a step S305, a via hole extending through the passivation layer and being opposite to a second electrode is formed by a third mask (Mask3) process.

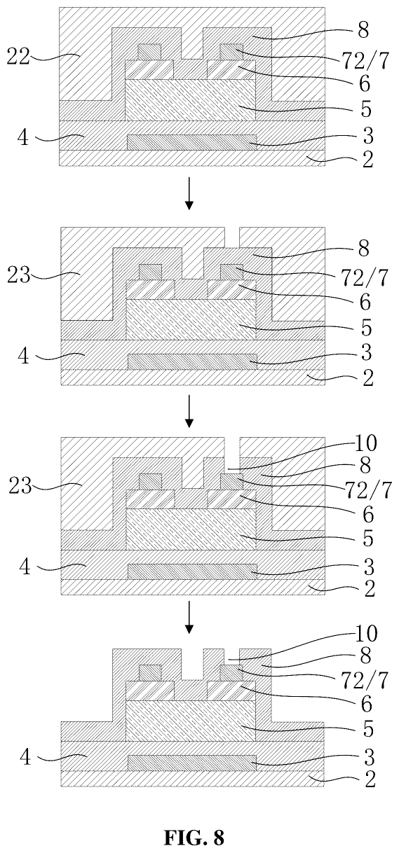

As shown in FIG. 8, a third photoresist film 22 is coated on the passivation layer 8, and then the third photoresist film 22 is patterned through a third mask (Mask 3) to form a third photoresist pattern 23. Sequentially, the passivation layer 8 is etched using the third photoresist pattern 23 as a mask to form a via hole 10 extending through the passivation layer 8. Finally, the third photoresist pattern 23 is removed.

Specifically, the formed via hole 10 is connected to the second electrode 72 of the second metal layer 7.

In a step S306, a transparent conductive layer disposed in the via hole and extending to the passivation layer is formed by a fourth mask (Mask4) process.

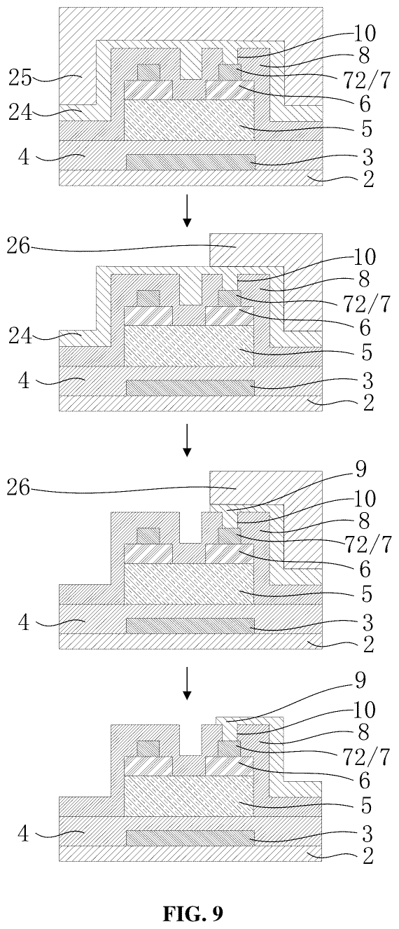

As shown in FIG. 9, a transparent electrode film 24 and a fourth photoresist film 25 are sequentially covered on the passivation layer 8 with the via hole 10, and then the transparent electrode film 24 is patterned by the fourth mask (Mask4) to form a fourth photoresist pattern 26. Sequentially, the transparent electrode film 24 is etched using the fourth photoresist pattern 26 as a mask to form a transparent conductive layer 9. Finally, the fourth photoresist pattern 26 is removed.

Specifically, the formed transparent conductive layer 9 is electrically connected to the second electrode 72 of the second metal layer 7 through the via hole 10.

In the photosensitive thin film transistor 1 of the embodiments of the present disclosure, at least one portion of the first orthographic projection of the second metal layer 7 on the substrate 2 is in the second orthographic projection of the photosensitive ohmic contact layer 6 on the substrate 2. Also, a distance between at least one edge of the first orthographic projection in the second orthographic projection and the second orthographic projection is greater than 0, and the distance is within a preset range. Thus, at least one side of the photosensitive ohmic contact layer 6 protrudes from the corresponding second metal layer 7, which reduces an area covered by the second metal layer 7 of the photosensitive ohmic contact layer 6, thereby increasing an irradiated area of the photosensitive ohmic contact layer 6, which is conducive to improving the photocurrent responsiveness of the photosensitive thin film transistor 1. Furthermore, the photosensitive thin film transistor 1 of the embodiments of the present disclosure can be formed by using the four mask (4Mask) process, which is beneficial to improve production efficiency.

An embodiment of the present disclosure also provides a photosensitive device. The photosensitive device includes a plurality of semiconductor devices in the foregoing embodiments.

Specifically, the photosensitive device may be a display device with both a display function and a light sensing function. For example, the photosensitive device also includes a plurality of pixel thin film transistors. The plurality of photosensitive thin film transistors and the plurality of pixel thin film transistors are arranged on to same array substrate. The photosensitive device also includes a color filter substrate facing the array substrate. Apparently, the photosensitive device can also only have the light sensing function, and there is no limitation here.

In the photosensitive device of the present disclosure, at least one portion of the first orthographic projection of the second metal layer on the substrate is in the second orthographic projection of the photosensitive ohmic contact layer on the substrate. Also, a distance between at least one edge of the first orthographic projection and an edge of the second orthographic projection is greater than 0, and the distance is within a preset range. Thus, at least one side of the photosensitive ohmic contact layer protrudes from the corresponding second metal layer, which reduces an area covered by the second metal layer of the photosensitive ohmic contact layer, thereby increasing an irradiated area of the photosensitive ohmic contact layer, which is conducive to improving the photocurrent responsiveness of the photosensitive thin film transistor. Furthermore, the photosensitive thin film transistor of the embodiments of the present disclosure can be formed by using the four mask (4Mask) process, which is beneficial to improve production efficiency.

The semiconductor device and the photosensitive device of the embodiments of the present disclosure are described in detail above. In this specification, specific examples are used to illustrate the principle and the embodiments of the present disclosure. The description of the above embodiment is only used to help understand the method and core idea of the present disclosure. At the same time, for those skilled in the art, based on the idea of the present disclosure, there will be changes in the specific embodiments and the scope of application. In summary, the contents of this specification should not be construed as a restriction on the present disclosure.

What is claimed is:

1. A semiconductor device, comprising a substrate and a photosensitive thin film transistor disposed on the substrate, wherein the photosensitive thin film transistor is a bottom gate structure, and the photosensitive thin film transistor comprises:
a first metal layer disposed on the substrate;
an insulating layer covering the substrate and the first metal layer;
a photosensitive semiconductor layer disposed on the insulating layer and aligned with the first metal layer;
a photosensitive ohmic contact layer disposed on the photosensitive semiconductor layer and comprising a first photosensitive ohmic contact portion and a second photosensitive ohmic contact portion that are arranged at intervals; and
a second metal layer disposed on the first photosensitive ohmic contact portion and the second photosensitive ohmic contact portion,
wherein an orthographic projection of the second metal layer on the substrate is a first orthographic projection, an orthographic projection of the photosensitive ohmic contact layer on the substrate is a second orthographic projection, at least one portion of the first orthographic projection is in the second orthographic projection, a distance between at least one edge of the first orthographic projection and an edge of the second orthographic projection is greater than 0, and the distance is within a preset range.

2. The semiconductor device according to claim 1, wherein the preset range is greater than or equal to 0.4 micrometers.

3. The semiconductor device according to claim 1, wherein the preset range is greater than 0 micrometers and less than or equal to 0.8 micrometers.

4. The semiconductor device according to claim 1, wherein the second metal layer comprises a first electrode disposed on the first photosensitive ohmic contact portion and a second electrode disposed on the second photosensitive ohmic contact portion; and
wherein an orthographic projection of the first electrode on the substrate is in an orthographic projection of the first photosensitive ohmic contact portion on the substrate, and/or an orthographic projection of the second electrode on the substrate is in an orthographic projection of the second photosensitive ohmic contact portion on the substrate.

5. The semiconductor device according to claim 4, wherein distances of any two points of an edge of the orthographic projection of the first electrode on the substrate to an edge of the orthographic projection of the first photosensitive ohmic contact portion on the substrate are equal.

6. The semiconductor device according to claim 4, wherein distances of any two points of an edge of the orthographic projection of the second electrode on the substrate to an edge of the orthographic projection of the second photosensitive ohmic contact portion on the substrate are equal.

7. The semiconductor device according to claim 1, wherein material of the photosensitive semiconductor layer comprises an amorphous silicon, and material of the photosensitive ohmic contact layer comprises a doped amorphous silicon.

8. The semiconductor device according to claim 1, wherein the photosensitive semiconductor layer comprises a first side surface and a second side surface that are opposite to each other; and
wherein a side of the first photosensitive ohmic contact portion away from the second photosensitive ohmic contact portion is on a same plane as the first side surface of the photosensitive semiconductor layer, and a side of the second photosensitive ohmic contact portion away from the first photosensitive ohmic contact portion is on a same plane as the second side surface of the photosensitive semiconductor layer.

9. The semiconductor device according to claim 1, wherein the photosensitive semiconductor layer and the photosensitive ohmic contact layer are formed through a same mask process.

10. The semiconductor device according to claim 1, further comprising: a passivation layer, a via hole, and a transparent conductive layer, wherein the passivation layer covers the insulating layer, the photosensitive semiconductor layer, the photosensitive ohmic contact layer, and the second metal layer; the via hole extends through the passivation layer and is connected to the second metal layer; the transparent conductive layer is disposed in the via hole and extends to the passivation layer; and the transparent conductive layer is electrically connected to the second metal layer through the via hole.

11. A semiconductor device, comprising a substrate and a photosensitive thin film transistor disposed on the substrate, wherein the photosensitive thin film transistor comprises:
a first metal layer disposed on the substrate;
an insulating layer covering the substrate and the first metal layer;
a photosensitive semiconductor layer disposed on the insulating layer and aligned with the first metal layer;
a photosensitive ohmic contact layer disposed on the photosensitive semiconductor layer and comprising a first photosensitive ohmic contact portion and a second photosensitive ohmic contact portion that are arranged at intervals; and
a second metal layer disposed on the first photosensitive ohmic contact portion and the second photosensitive ohmic contact portion,
wherein an orthographic projection of the second metal layer on the substrate is a first orthographic projection, an orthographic projection of the photosensitive ohmic contact layer on the substrate is a second orthographic projection, at least one portion of the first orthographic projection is in the second orthographic projection, a distance between at least one edge of the first orthographic projection and an edge of the second orthographic projection is greater than 0, and the distance is within a preset range.

12. The semiconductor device according to claim 11, wherein the preset range is greater than or equal to 0.4 micrometers.

13. The semiconductor device according to claim 11, wherein the preset range is greater than 0 micrometers and less than or equal to 0.8 micrometers.

14. The semiconductor device according to claim 11, wherein the second metal layer comprises a first electrode disposed on the first photosensitive ohmic contact portion and a second electrode disposed on the second photosensitive ohmic contact portion; and
wherein an orthographic projection of the first electrode on the substrate is in an orthographic projection of the first photosensitive ohmic contact portion on the substrate, and/or an orthographic projection of the second electrode on the substrate is in an orthographic projection of the second photosensitive ohmic contact portion on the substrate.

15. The semiconductor device according to claim 14, wherein distances of any two points of an edge of the orthographic projection of the first electrode on the substrate to an edge of the orthographic projection of the first photosensitive ohmic contact portion on the substrate are equal.

16. The semiconductor device according to claim 14, wherein distances of any two points of an edge of the orthographic projection of the second electrode on the substrate to an edge of the orthographic projection of the second photosensitive ohmic contact portion on the substrate are equal.

17. The semiconductor device according to claim 11, wherein material of the photosensitive semiconductor layer comprises an amorphous silicon, and material of the photosensitive ohmic contact layer comprises a doped amorphous silicon.

18. The semiconductor device according to claim 11, wherein the photosensitive semiconductor layer comprises a first side surface and a second side surface that are opposite to each other; and
wherein a side of the first photosensitive ohmic contact portion away from the second photosensitive ohmic contact portion is on a same plane as the first side surface of the photosensitive semiconductor layer, and a side of the second photosensitive ohmic contact portion away from the first photosensitive ohmic contact portion is on a same plane as the second side surface of the photosensitive semiconductor layer.

19. The semiconductor device according to claim 11, further comprising: a passivation layer, a via hole, and a transparent conductive layer, wherein the passivation layer covers the insulating layer, the photosensitive semiconductor layer, the photosensitive ohmic contact layer, and the second metal layer; the via hole extends through the passivation layer and is connected to the second metal layer; the transparent conductive layer is disposed in the via hole and extends to the passivation layer; and the transparent conductive layer is electrically connected to the second metal layer through the via hole.

20. A photosensitive device, comprising: a semiconductor device, wherein the semiconductor device comprises a substrate and a photosensitive thin film transistor disposed on the substrate, and the photosensitive thin film transistor comprises:
a first metal layer disposed on the substrate;
an insulating layer covering the substrate and the first metal layer;
a photosensitive semiconductor layer disposed on the insulating layer and aligned with the first metal layer;
a photosensitive ohmic contact layer disposed on the photosensitive semiconductor layer and comprising a first photosensitive ohmic contact portion and a second photosensitive ohmic contact portion that are arranged at intervals; and
a second metal layer disposed on the first photosensitive ohmic contact portion and the second photosensitive ohmic contact portion,
wherein an orthographic projection of the second metal layer on the substrate is a first orthographic projection, an orthographic projection of the photosensitive ohmic contact layer on the substrate is a second orthographic projection, at least one portion of the first orthographic projection is in the second orthographic projection, a distance between at least one edge of the first orthographic projection and an edge of the second orthographic projection is greater than 0, and the distance is within a preset range.
